(19) United States
(12) Patent Application Publication
(10) Pub. No.: US 2024/0405162 A1
(43) Pub. Date: Dec. 5, 2024

(54) RGB MICRO-LIGHT-EMITTING DIODE HAVING VERTICALLY-STACKED STRUCTURE WITH CORNER MESA CONTACT STRUCTURES AND MANUFACTURING METHOD THEREOF

(71) Applicant: SUNDIODE KOREA, Seoul (KR)

(72) Inventors: James Chinmo KIM, Mountain View, CA (US); Sungsoo YI, Sunnyvale, CA (US)

(21) Appl. No.: 18/418,199

(22) Filed: Jan. 19, 2024

(30) Foreign Application Priority Data
Jun. 5, 2023 (KR) 10-2023-0072481

(51) Int. Cl. H01L 33/38; H01L 33/00; H01L 33/06; H01L 33/20; H01L 33/44

(52) U.S. Cl. CPC H01L 33/387; H01L 33/0095; H01L 33/06; H01L 33/20; H01L 33/44

(57) ABSTRACT

The present inventive concept relates to an RGB micro-light-emitting diode having a vertically-stacked structure with corner mesa contact structures, and a manufacturing method thereof. The RGB micro-light-emitting diode having a vertically-stacked structure with corner mesa contact structures includes an n-type contact electrode layer, a first light-emitting structure, a common electrode layer, a second light-emitting structure, a tunnel junction layer, and a third light-emitting structure, which are sequentially stacked on a substrate. The RGB micro-light-emitting diode with a reduced unit area can be easily manufactured by forming the corner mesa contact structure on each of the n-type contact electrode layers by etching the vertically-stacked structure, forming contact structures on the n-type contact electrode layers, followed by electrical connection.

### CROSS-REFERENCE TO RELATED PATENT APPLICATION

This application claims the benefit of Korean Patent Application No. 10-2023-0072481, filed on Jun. 5, 2023, in the Korean Intellectual Property Office, the disclosure of which is incorporated herein in its entirety by reference.

### BACKGROUND OF THE INVENTIVE CONCEPT

### 1. Field of the Inventive Concept

The present inventive concept is related to an RGB micro light-emitting diode consisting of three light sources of red (R), green (G), and blue (B), and more specifically, to an RGB micro light-emitting diode having a vertically-stacked structure with corner mesa contact structures, and a manufacturing method thereof.

### 2. Description of the Related Art

A light-emitting diode (LED) is a semiconductor device that emits light when a current flows in the forward direction, and it includes a PN junction where an n-type semiconductor and a n-type semiconductor are formed on active layers that generate light. A common method of manufacturing LEDs involves adding Mg to GaN to form a p-type semiconductor and adding Si to form an n-type semiconductor. LEDs are often used in displays such as TVs, billboards etc. signboards, and offer the advantages of low power consumption and long lifespan compared to traditional light sources.

However, traditional LEDs with a mesa structure fabricated by etching have issues with the active layers being exposed to the outside, in which the exposure leads to reduced internal quantum efficiency due to surface recombination at the exposed regions. The exposed regions are also susceptible to a leakage current due to surface damage and contamination caused by the plasma used during etching. Moreover, the surface recombination generates heat at the semiconductor surface, leading to structural defects such as dark line defects, which in turn reduce the lifespan of the LED.

Therefore, there is a need for the development of a light-emitting diode that can minimize the exposure of the active layers.

Furthermore, there is a need for a method of electrically connecting each of the R, G and B sub-LEDs, when a micro light-emitting diode with vertically-stacked R, G and B sub-LEDs forms a single pixel, and thus there is also a need for the development of a structure that can improve efficiency when a current is applied into the micro light-emitting diode.

### SUMMARY OF THE INVENTIVE CONCEPT

The present inventive concept has been made in an effort to solve the above-described problems associated with prior art, and a first object of the present inventive concept is to provide an RGB micro-light-emitting diode having a vertically-stacked structure with corner mesa contact structures.

A second object of the present inventive concept is to provide a method of manufacturing an RGB micro-light-emitting diode having a vertically-stacked structure with corner mesa contact structures.

In order to achieve the above-mentioned first object, the present inventive concept provides an RGB micro-light-emitting diode having a vertically-stacked structure with corner mesa contact structures manufactured by etching a vertically-stacked structure comprising a substrate, an n-type contact electrode layer, a first light-emitting structure, a first tunnel junction layer, a common electrode layer, a second tunnel junction layer, a second light-emitting structure, and a third light-emitting structure, which are sequentially stacked.

In order to achieve the above-mentioned second object, the present inventive concept provides a method of manufacturing an RGB micro-light-emitting diode having a vertically-stacked structure with corner mesa contact structures.

The RGB micro-light-emitting diode may be manufactured by forming contact holes by etching a vertically-stacked structure, forming a pixel mesa structure including the contact holes at corners to create a vertically-stacked structure including corner mesa contact structures, further forming contact structures in a region away from the pixel mesa structure on the vertically-stacked structure, and then electrically connecting the contact structures by passivation and metal contact deposition.

The RGB micro-light-emitting diode may be manufactured by forming a pixel mesa structure by etching a vertically-stacked structure, depositing and planarizing a protective film on the pixel mesa structure, forming a contact hole by etching the vertically-stacked structure, removing the remaining protective film to create a vertically-stacked structure having corner mesa contact structures, further forming contact structures in a region away from the pixel mesa structure on the vertically-stacked structure, and then electrically connecting the contact structures by passivation and metal contact deposition.

The corner mesa contact structures may comprise first to third corner mesa contact structures. The first corner mesa contact structure may be formed by removing the higher layers relative to the common electrode layer to expose a portion of the upper surface of the common electrode layer, the second corner mesa contact structure may be formed by removing the higher layers relative to the second light-emitting structure to expose a portion of the upper surface of the second light-emitting structure, and the third corner mesa contact structure may be formed by removing the higher layers relative to the third light-emitting structure to expose a portion of the upper surface of the third n-type semiconductor layer.

The contact structures may consist of a first contact structure and a second contact structure. The first contact structure may be formed by removing the higher layers relative to a second n-type contact electrode layer to expose a portion of the upper surface of the second n-type contact electrode layer, and the second contact structure may be formed by removing the higher layers relative to a first n-type contact electrode layer to expose a portion of the upper surface of the first n-type contact electrode layer.

The metal contact may be used as a first wiring layer, a second wiring layer, and a common contact electrode layer. The first wiring layer electrically connects the second light-emitting structure and the n-type contact electrode layer, and the second wiring layer electrically connects the third light-emitting structure and the n-type contact electrode layer. The common contact electrode layer may cover the common electrode layer and the top of the third light-emitting structure.

According to the present inventive concept as described above, the micro-light-emitting diode has a mesa structure that is approximately perpendicular at the corners, which minimizes the exposure of the active layers to the external environment, thereby reducing the occurrence of surface recombination, which is a primary cause of leakage current. As a result, it is possible to increase the lifespan of the micro-light-emitting diode. Moreover, due to the vertical etching direction, the manufacturing process is easier.

Light-emitting sub-structures that generate light with different wavelengths are vertically stacked on the substrate to reduce the unit area of the micro-light-emitting diode, and by means of a current blocking layer structure, each of the light-emitting structures can be individually controlled.

### BRIEF DESCRIPTION OF THE DRAWINGS

The above and other features and advantages of the present inventive concept will become more apparent by describing in detail exemplary embodiments thereof with reference to the attached drawings in which:

FIG. 1 shows a cross-sectional view and a perspective view of a micro-light-emitting diode according to an embodiment of the present inventive concept;

FIGS. 2 to 10 show perspective views illustrating the process of manufacturing a micro-light-emitting diode according to the first embodiment of the present inventive concept;

FIG. 11 shows a cross-sectional view and a perspective view of a micro-light-emitting diode according to an embodiment of the present inventive concept; and

FIGS. 12 to 22 show perspective views illustrating the process of manufacturing a micro-light-emitting diode according to a second embodiment of the present inventive concept.

### DETAILED DESCRIPTION OF THE INVENTIVE CONCEPT

As the present inventive concept allows for various changes and numerous embodiments, particular embodiments will be illustrated in the drawings and described in detail in the written description. However, this is not intended to limit the present inventive concept to particular modes of practice, and it is to be appreciated that all changes, equivalents, and substitutes that do not depart from the spirit and technical scope of the present inventive concept are encompassed in the present inventive concept. In the drawings, like reference numerals have been used throughout to designate like elements.

Unless defined otherwise, all terms used herein including technical or scientific terms have the same meaning as those generally understood by those skilled in the art to which the present inventive concept pertains. It will be further understood that terms defined in dictionaries that are commonly used should be interpreted as having meanings that are consistent with their meanings in the context of the relevant art and should not be interpreted as having ideal or excessively formal meanings unless clearly defined in the present application.

In this specification, “LED” and “light-emitting diode” have the same meaning and thus may be used interchangeably throughout the specification.

In this specification, when an element such as a layer, region or substrate is referred to as being “on” another element, it means that it may be directly present on the other element and there may also be intervening elements between them.

In this specification, the contact holes are formed independently of the order and are not interpreted as being limited to the order of the manufacturing method of the embodiment.

Hereinafter, various embodiments of the present inventive concept will be described in more detail with reference to the accompanying drawings.

### First Embodiment

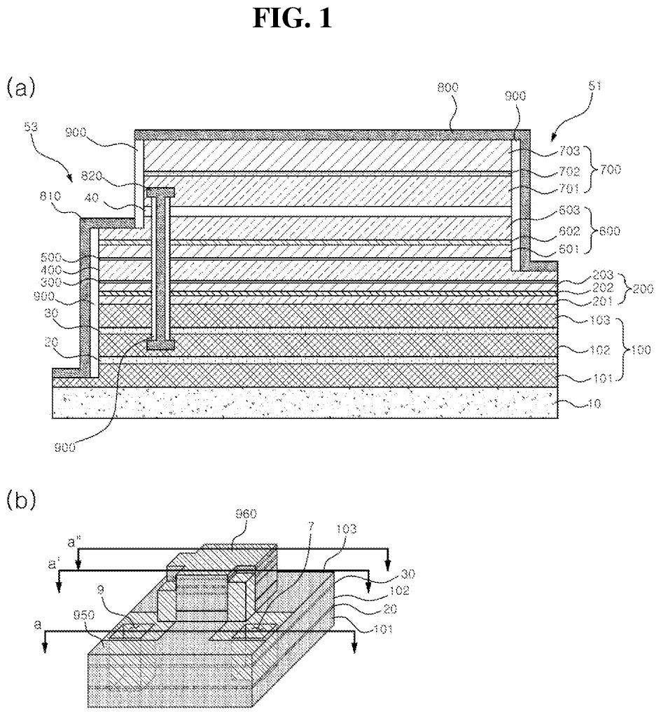

FIG. 1 shows a cross-sectional view and a perspective view of an RGB micro-light-emitting diode according to an embodiment of the present inventive concept. In FIG. 1, (a) is a cross-sectional view obtained by cutting the perspective view of (b) in the directions of a, a′ and a″ and overlapping them. Some parts are somewhat exaggerated in the cross-sectional views for a convenient representation of the connections of the wiring layers, which are easily understood by those skilled in the art.

Referring to FIG. 1, the RGB micro-light-emitting diode according to the present inventive concept may comprise a substrate 10, an n-type contact electrode layer 100, a first light-emitting structure 200, a first tunnel junction layer 300, a common electrode layer 400, a second tunnel junction layer 500, a second light-emitting structure 600, and a third light-emitting structure 700.

The substrate 10 may comprise at least one selected from the group consisting of Al₂O₃, SiC, GaN, GaP, GaAs, InP, and ZnO but is not limited thereto, and any substrate used for light-emitting diodes can be used.

The n-type contact electrode layer 100 may comprise a first n-type contact electrode layer 101, a second n-type contact electrode layer 102, and a third n-type contact electrode layer 103. The first to third n-type contact electrode layers 101 to 103 may be sequentially stacked on substrate 10.

The RGB micro-light-emitting diode may comprise a first current blocking layer 20 formed between the first n-type contact electrode layer 101 and the second n-type contact electrode layer 102, and a second current blocking layer 30 formed between the second n-type contact electrode layer 102 and the third n-type contact electrode layer 103.

The first current blocking layer 20 and the second current blocking layer 30 may consist of a p-type semiconductor or an insulating material, respectively.

The first light-emitting structure 200 may consist of a first n-type semiconductor layer 201, a first active layer 202, and a first p-type semiconductor layer 203, and the first n-type semiconductor layer 201 may be bonded to the third n-type contact electrode layer 103. However, the first n-type semiconductor layer 201 and the third n-type contact electrode layer 103 may be the same layer. The first p-type semiconductor layer 203 may be bonded to the first tunnel junction layer 300.

A third current blocking layer 40 may be formed between the second light-emitting structure 600 and the third light-emitting structure 700, and the third current blocking layer 40 may consist of a p-type semiconductor or an insulating material.

The second light-emitting structure 600 may consist of a second p-type semiconductor layer 601, a second active layer 602, and a second n-type semiconductor layer 603. The second p-type semiconductor layer 601 may be bonded to the second tunnel junction layer 500, and the second n-type semiconductor layer 603 may be bonded to the third current blocking layer 40.

The third light-emitting structure 700 may consist of a third n-type semiconductor layer 701, a third active layer 702, and a third p-type semiconductor layer 703. The third n-type semiconductor layer 701 may be bonded to the third current blocking layer 40, and a common contact electrode layer 800 may be formed on the third p-type semiconductor layer 703.

The first to third active layers may have a multi-quantum well structure.

The first light-emitting structure 200 is in contact with the third n-type contact electrode layer 103, the second light-emitting structure 600 is in contact with the first n-type contact electrode layer 101, and the third light-emitting structure 700 is in contact with the second n-type contact electrode layer 102. As a result, the light generated from the light-emitting structures 200, 600, and 700 can be selectively controlled depending on the polarity of the applied voltage.

The first light-emitting structure 200 may generate light of a first wavelength, the second light-emitting structure 600 may generate light of a second wavelength that is longer than the first wavelength, and the third light-emitting structure 700 may generate light of a third wavelength that is longer than the second wavelength.

The light of the first wavelength may be blue (B), the light of the second wavelength may be green (G), and the light of the third wavelength may be red (R).

The common electrode layer 400 may consist of an n-type semiconductor layer. The first tunnel junction layer 300 may be bonded to the bottom of common electrode layer 400, and the second tunnel junction layer 500 may be bonded to the top of common electrode layer 400. The first tunnel junction layer 300 and the second tunnel junction layer 500 may comprise n⁺⁺-GaN layers and p⁺⁺-GaN layers, respectively, which are sequentially stacked in a symmetrical structure with respect to the common electrode layer 400, and may be reverse biased to change the current-flow direction in the common electrode layer 400. Moreover, since the first p-type semiconductor layer 203 of the first light-emitting structure 200 is disposed on the bottom of the common electrode layer 400 and the second p-type semiconductor layer 601 of the second light-emitting structure 600 is disposed on the top of the common electrode layer 400, the first light-emitting structure 200 and the second light-emitting structure 600 are commonly connected by the common electrode layer 400, but the directions of the current flow may be opposite to each other.

Since the RGB micro-light-emitting diode has a pixel mesa structure, it has a shape of two squares joined together when viewed from the top. Furthermore, the small square planar shape is defined as having four corners, which are etched to form first to third corner mesa contact structures. The large square planar shape has a first contact structure and a second contact structure.

A first corner mesa contact structure is formed at a first corner, and the first corner mesa contact structure is formed by removing the higher layers relative to the common electrode layer 400 to expose a portion of the upper surface of the common electrode layer 400.

A second corner mesa contact structure is formed at a second corner in a first direction, which, in the perspective view of the figure, is vertical to the first corner mesa contact structure. The second corner mesa contact structure is formed by removing the higher layers relative to the second n-type semiconductor layer 603 to expose a portion of the upper surface of the second n-type semiconductor layer 603.

A third corner mesa contact structure is formed at a third corner in a second direction, which, in the perspective view of the figure, is transverse to the second corner mesa contact structure. The third corner mesa contact structure is formed by removing the higher layers relative to the third n-type semiconductor layer 701 removed to expose a portion of the upper surface of the third n-type semiconductor layer 701.

The formation of the first corner mesa contact structure and the second corner mesa contact structure as described above can minimize the area occupied by the mesa structure. Moreover, by forming the corner mesa contact structures by etching the corners of the mesa structure, the side surface exposed by etching is reduced to less than half compared to the conventional approaches that form etched structures inside the mesa structure away from the corners, which minimizes the exposure of the active layers, thereby maximizing the efficiency of the micro-light-emitting diode.

Furthermore, when viewed from the top, the micro-light-emitting diode of the present inventive concept exhibits the highest light emission intensity in the center of the square plane, while the corner portions have relatively lower light emission intensity. This means that by utilizing the corner portions as contact structures, the light emission efficiency of the micro-light-emitting diode can be improved.

The first contact structure is formed in the same direction as the first corner mesa contact structure and the second corner mesa contact structure. The first contact structure is formed by removing the higher layers relative to the second n-type contact electrode layer 102 to expose a portion of the upper surface of the second n-type contact electrode layer 102.

The second contact structure is located in a direction that is spaced apart from the first contact structure and is formed in a third direction, which is diagonal to the first corner mesa contact structure. The second contact structure is formed by removing the higher layers relative to the first n-type contact electrode layer 101 to expose a portion of the upper surface of the first n-type contact electrode layer 101.

The RGB micro-light-emitting diode may comprise: a first wiring layer 810 electrically connecting the second n-type semiconductor layer 603 and the first n-type contact electrode layer 101; a second wiring layer 820 electrically connecting the third n-type semiconductor layer 701 and the second n-type contact electrode layer 102; and a common contact electrode layer 800 covering the exposed surface of the common electrode layer 400 and the top of the third p-type semiconductor layer 703.

The following process is performed to manufacture an RGB micro-light-emitting diode having the structure illustrated in FIG. 1.

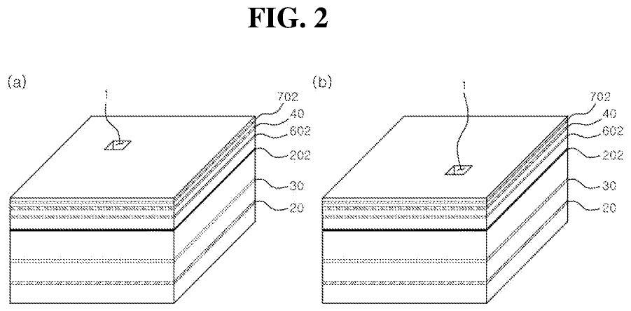

FIGS. 2 to 10 show perspective views illustrating the process of manufacturing a micro-light-emitting diode according to the first embodiment of the present inventive concept. The structure obtained by rotating (a) in FIGS. 2 to 10 by 180° is shown in (b), respectively.

Referring to FIGS. 2 to 10, the micro-light-emitting diode may be manufactured by a process including: a first step of forming a first contact hole; a second step of forming a second contact hole; a third step of forming a third contact hole; a fourth step of forming a fourth contact hole; a fifth step of forming a fifth contact hole; a sixth step of forming a vertically-stacked structure having corner mesa contact structures on a third n-type semiconductor layer by etching the vertically-stacked structure into a rectangular shape including the first to third contact holes at the corners; a seventh step of depositing a passivation layer on the surface of the vertically-stacked structure having the corner mesa contact structures; an eighth step of etching the passivation layer for electrode connection of the vertically-stacked structure; and a ninth step of forming a metal contact to connect to the top of the etched vertically-stacked structure.

Referring to FIG. 2, the vertically-stacked structure shown in FIG. 1 is formed on the substrate. The vertically-stacked structure refers to the structure formed up to the third p-type semiconductor layer 703 through the MOCVD process.

In the first step, a first contact hole 1 is formed by etching the vertically-stacked structure to form a first corner mesa contact structure on the vertically-stacked structure. One of the common electrode layer 400, the second n-type semiconductor layer 603, and the third n-type semiconductor layer 701 is exposed through the first contact hole 1. The first contact hole 1 may be formed by removing the higher layers relative to the common electrode layer 400 to expose a portion of the upper surface of the common electrode layer 400.

In this embodiment, it is described that a portion of the upper surface of the common electrode layer 400 is exposed through the first contact hole 1, but the layers exposed through the contact holes can be easily changed. That is, in the present inventive concept, the three contact holes expose the common electrode layer 400, the second n-type semiconductor layer 603, and the third n-type semiconductor layer 701, respectively, but two or more contact holes do not share the exposed layers.

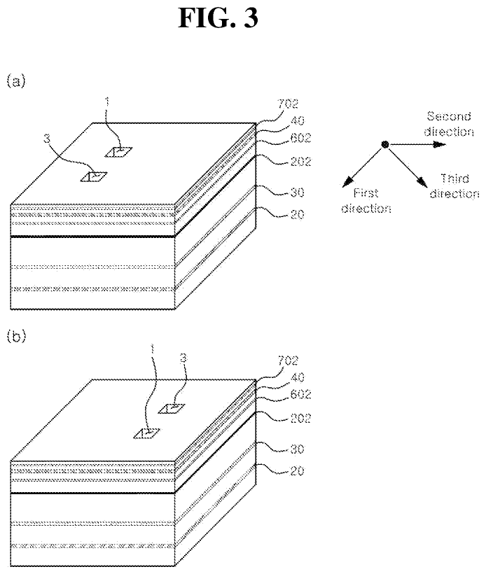

Referring to FIG. 3, in the second step, a second contact hole 3 is formed by etching the vertically-stacked structure to form a second corner mesa contact structure in a first direction, which is vertical to the first contact hole 1 on the vertically-stacked structure. One of the common electrode layer 400, the second n-type semiconductor layer 603, and the third n-type semiconductor layer 701 is exposed through the second contact hole 3. The second contact hole 3 may be formed by removing the higher layers relative to the second n-type semiconductor layer 603 to expose a portion of the upper surface of the second n-type semiconductor layer 603.

In this embodiment, it is described that a portion of the upper surface of the second n-type semiconductor layer 603 is exposed through the second contact hole 3, but the layers exposed through the contact holes can be easily changed.

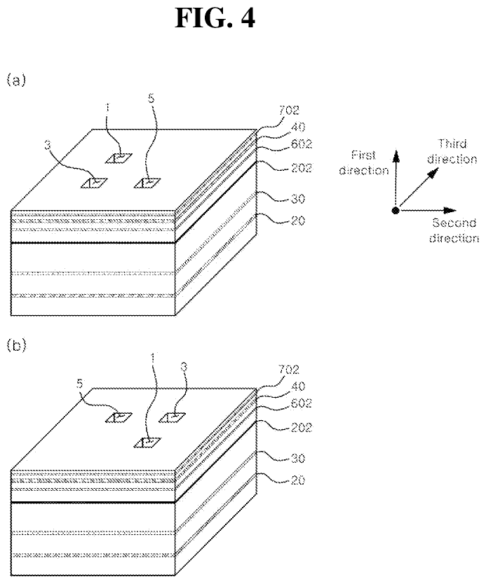

Referring to FIG. 4, in the third step, a third contact hole 5 is formed by etching the vertically-stacked structure to form a third corner mesa contact structure in a second direction, which, in the perspective view of the figure, is transverse to the second contact hole 3 on the vertically-stacked structure. One of the common electrode layer 400, the second n-type semiconductor layer 603, and the third n-type semiconductor layer 701 is exposed through the third contact hole 5. The third contact hole 5 may be formed by removing the higher layers relative to the third n-type semiconductor layer 701 to expose a portion of the upper surface of the third n-type semiconductor layer 701.

In this embodiment, it is described that a portion of the upper surface of the third n-type semiconductor layer 701 is exposed through the third contact hole 5, but the layers exposed through the contact holes can be easily changed.

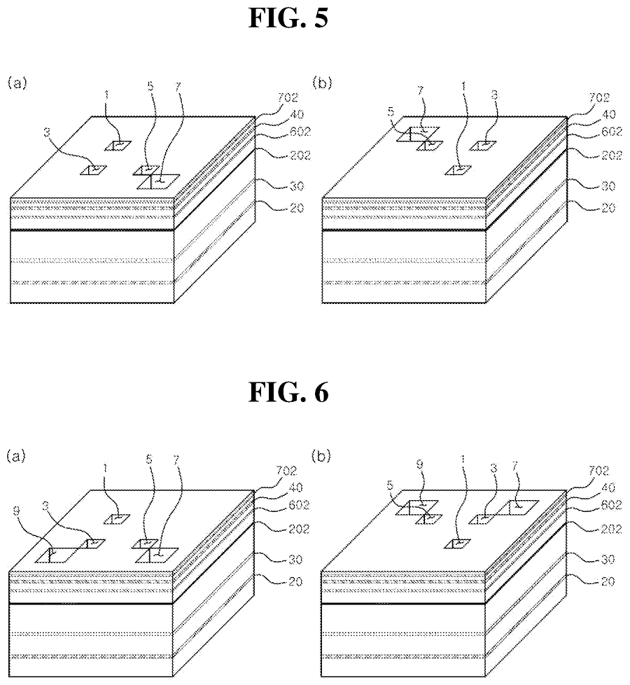

Referring to FIG. 5, in the fourth step, a fourth contact hole 7 is formed by etching the vertically-stacked structure to form a first contact structure in a third direction, which is diagonal to the first contact hole 1 on the vertically-stacked structure. The fourth contact hole 7 may be formed by removing the higher layers relative to the second n-type contact electrode layer 102 to expose a portion of the upper surface of the second n-type contact electrode layer 102.

Referring to FIG. 6, in the fifth step, a fifth contact hole 9 is formed by etching the vertically-stacked structure to form a second contact structure in the second direction, which, in the perspective view of the figure, is transverse to the fourth contact hole 7, and in the first direction, which, in the perspective view of the figure, is vertical to the first contact hole 1, on the vertically-stacked structure. The fifth contact hole 9 may be formed by removing the higher layers relative to the first n-type contact electrode layer 101 to expose a portion of the upper surface of the first n-type contact electrode layer 101.

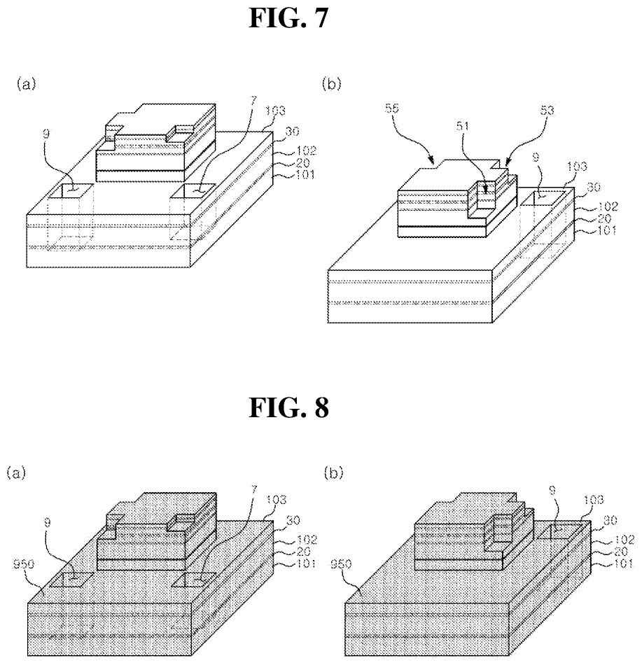

Referring to FIG. 7, in the sixth step, a vertically-stacked structure including the corner mesa contact structures is manufactured by etching the vertically-stacked structure, which includes the first contact hole 1 at the first corner, the second contact hole 3 at the second corner, the third contact hole 5 at the third corner, and no contact hole at the fourth corner, into a rectangular shape, down to the surface of the third n-type contact electrode layer 103.

Referring to FIG. 8, in the seventh step, a passivation layer 950 is deposited on the vertically-stacked structure. SiO₂, Al₂O₃, or SiNₓ may be used to deposit the passivation layer 950 but is not limited thereto. The passivation layer 950 may be the insulating layer 900 of FIG. 1. For a clearer illustration, the following drawings allow the main layers to be visible even after the passivation layer is deposited, but in reality, the main layers are not exposed to the outside.

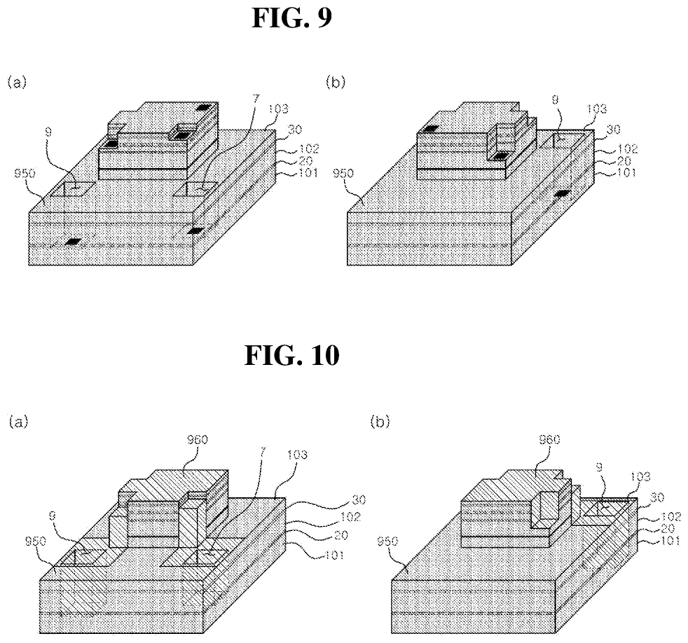

Referring to FIG. 9, in the eighth step, the passivation layer 950 is etched for electrical connection of the contact structures.

Referring to FIG. 10, in the ninth step, a metal contact 960 is deposited on the etched vertically-stacked structure to manufacture an RGB micro-light-emitting diode that electrically connects the respective contact structures.

The metal contact 960 consists of a common contact electrode layer 800, a first wiring layer 810, and a second wiring layer 820. The first wiring layer 810 is formed on the exposed portions of the second n-type semiconductor layer 603 and the second n-type contact electrode layer 102, and the second wiring layer 820 is formed on the exposed portions of the third n-type semiconductor layer 701 and the first n-type contact electrode layer 101. The common contact electrode layer 800 is formed on the exposed portions of the common electrode layer 400 and the third p-type semiconductor layer 703 for electrically connecting each other.

### Second Embodiment

A different process is performed to manufacture an RGB micro-light-emitting diode having a vertically-stacked structure with corner mesa contact structures using the same vertically-stacked structure as the first embodiment.

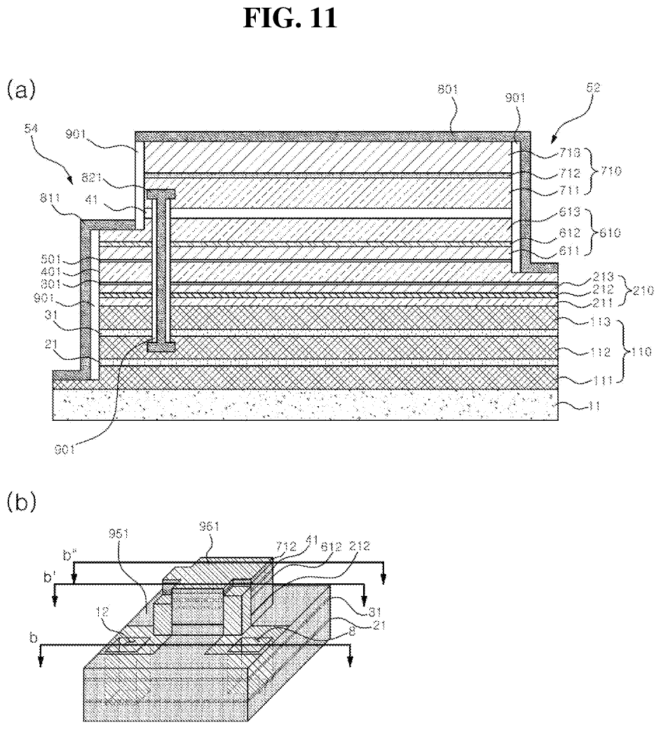

FIG. 11 is a cross-sectional view and a perspective view of a micro-light-emitting diode according to an embodiment of the present inventive concept. In FIG. 11, (a) is a cross-sectional view obtained by cutting the perspective view of (b) in the directions of b, b′ and b″ and overlapping them. The structure illustrated in FIG. 11 is the same as that of FIG. 1.

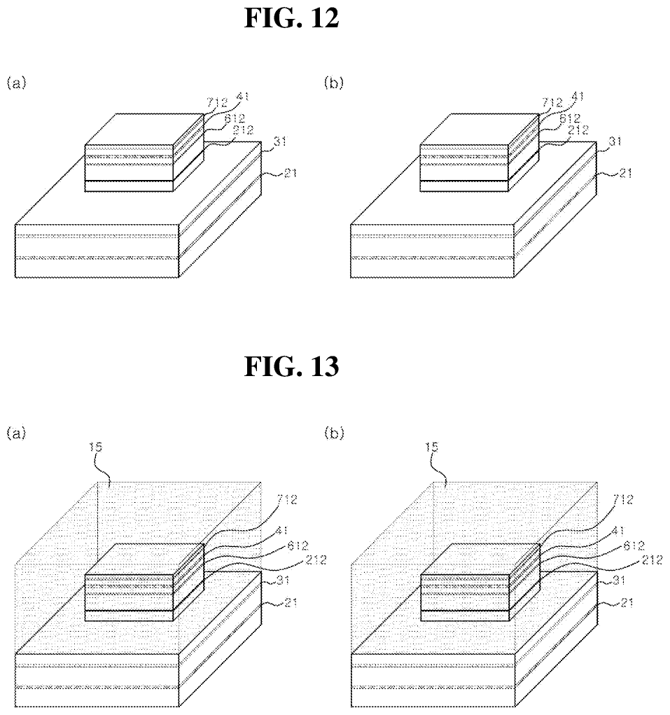

FIGS. 12 to 22 show perspective views illustrating the process of manufacturing an RGB micro-light-emitting diode according to a second embodiment of the present inventive concept. The structure obtained by rotating (a) in FIGS. 12 to 22 by 180° is shown in (b), respectively.

Referring to FIGS. 12 to 22, the RGB micro-light-emitting diode may be manufactured by a process including: a first step of etching a vertically-stacked structure into a rectangular shape to form a pixel mesa structure; a second step of depositing a protective layer on the vertically-stacked structure including the pixel mesa structure; a third step of removing a portion of the protective layer by performing chemical mechanical polishing (CMP) to planarize the top of the protective layer and the pixel mesa structure; a fourth step of forming a first contact hole to form a first corner mesa contact structure at a first corner of the pixel mesa structure; a fifth step of forming a second contact hole to form a second corner mesa contact structure at a second corner of the pixel mesa structure; a sixth step of forming a third contact hole to form a third corner mesa contact structure at a third corner of the pixel mesa structure; a seventh step of forming a vertically-stacked structure including first to third corner mesa contact structures by removing the remaining protective layer on the vertically-stacked structure; an eighth step of forming a fourth contact hole to form a first contact structure on the surface of the vertically-stacked structure etched in the first step; a ninth step of forming a fifth contact hole to form a second contact structure on the surface of the vertically-stacked structure etched in the first step; a tenth step of depositing a passivation layer on the surface of the vertically-stacked structure including the corner mesa contact structures and the contact structure formed in the ninth step; an eleventh step of etching the passivation layer formed in the tenth step for electrode connection; and a twelfth step of forming a metal contact to connect to the top of the vertically-stacked structure etched in the eleventh step to manufacture an RGB micro-light-emitting diode.

Referring to FIG. 12, the vertically-stacked structure shown in FIG. 1 is formed on the substrate. In the first step, a pixel mesa structure is formed by etching the vertically-stacked structure down to the top of a third n-type contact electrode layer 113 into a rectangular shape.

Referring to FIG. 13, in the second step, a protective layer 15 including the pixel mesa structure is formed on the third n-type contact electrode layer 113. The protective layer 15 may be made of the same material used for depositing the passivation layer in the first embodiment but is not limited thereto.

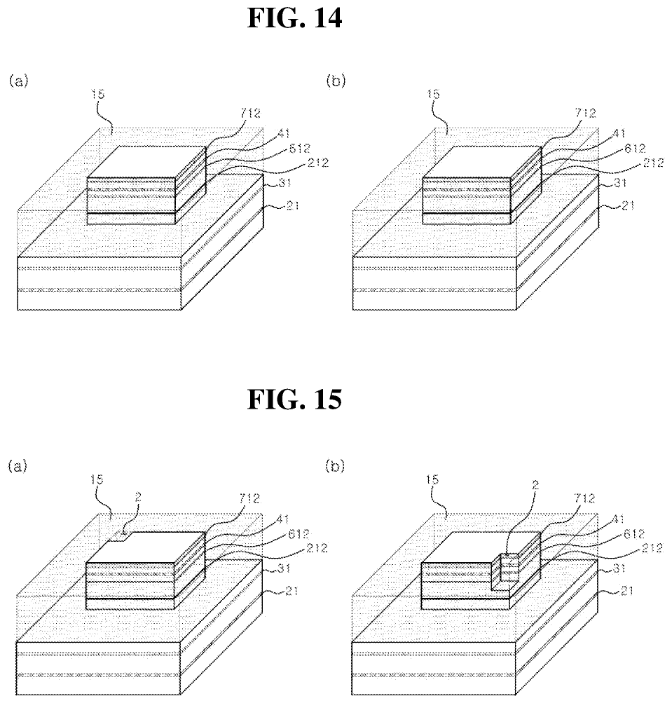

Referring to FIG. 14, in the third step, a portion of the protective layer 15 is removed by performing CMP down to the top of a third p-type semiconductor layer 713, which is the upper part of the pixel mesa structure, to planarize the top of the protective layer 850 and the pixel mesa structure.

Referring to FIG. 15, in the fourth step, a first contact hole 2 is formed to form a first corner mesa contact structure at a first corner of the pixel mesa structure. One of the common electrode layer 401, the second n-type semiconductor layer 613, and the third n-type semiconductor layer 711 is exposed through the first contact hole 2. The first contact hole 2 may be formed by removing the higher layers relative to the common electrode layer 401 to expose a portion of the upper surface of the common electrode layer 401.

In this embodiment, it is described that a portion of the upper surface of the common electrode layer is exposed through the first contact hole 2, but the layers exposed through the contact holes can be easily changed. That is, in the present inventive concept, the three contact holes expose the common electrode layer 401, the second n-type semiconductor layer 613, and the third n-type semiconductor layer 711, respectively, but two or more contact holes do not share the exposed layers.

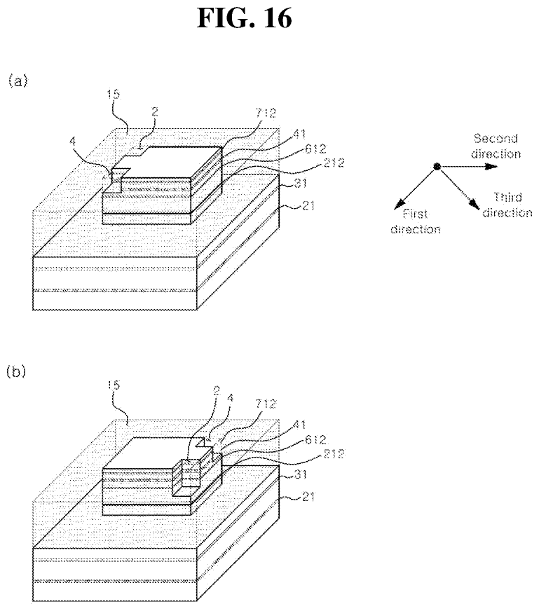

Referring to FIG. 16, in the fifth step, a second contact hole 4 is formed by etching the vertically-stacked structure to form a second corner mesa contact structure in a first direction, which, in the perspective view of the figure, is vertical to the first contact hole 1, on the pixel mesa structure. One of the common electrode layer 401, the second n-type semiconductor layer 613, and the third n-type semiconductor layer 711 is exposed through the second contact hole 4. The second contact hole 4 may be formed by removing the higher layers relative to the second n-type semiconductor layer 613 to expose a portion of the upper surface of the second n-type semiconductor layer 613.

In this embodiment, it is described that a portion of the upper surface of the second n-type semiconductor layer is exposed through the second contact hole 4, but the layers exposed through the contact holes can be easily changed.

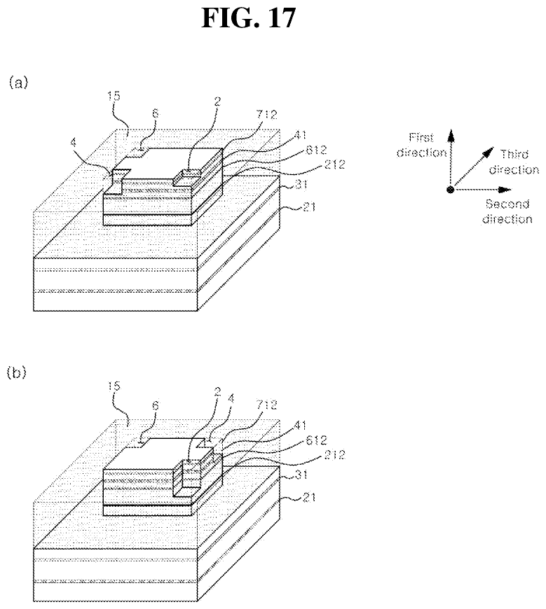

Referring to FIG. 17, in the sixth step, a third contact hole 6 is formed by etching the vertically-stacked structure to form a third corner mesa contact structure in a second direction, which, in the perspective view of the figure is horizontal to the second contact hole 4, on the pixel mesa structure. One of the common electrode layer 401, the second n-type semiconductor layer 613, and the third n-type semiconductor layer 711 is exposed through the third contact hole 6. The third contact hole 6 may be formed by removing the higher layers relative to the third n-type semiconductor layer 711 to expose a portion of the upper surface of the third n-type semiconductor layer 711.

In this embodiment, it is described that a portion of the upper surface of the third n-type semiconductor layer 711 is exposed through the third contact hole 6, but the layers exposed through the contact holes can be easily changed.

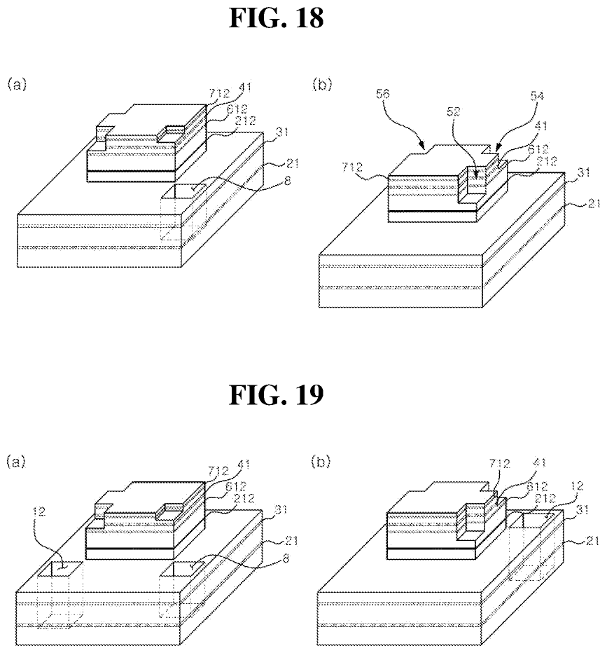

Referring to FIG. 18, in the seventh step, a vertically-stacked structure including the first to third corner mesa contact structures 52 to 56 is formed by removing the remaining protective layer 15 surrounding the pixel mesa structure in which the contact holes are formed. The first contact hole 2 corresponds to the first corner mesa contact structure 52, the second contact hole 4 corresponds to the second corner mesa contact structure 54, and the third contact hole 6 corresponds to the third corner mesa contact structure 56.

In the eighth step, in the vertically-stacked structure including the corner mesa contact structures, a fourth contact hole 8 is formed in a third direction, which is diagonal to the first corner mesa contact structure, on the surface of the vertically-stacked structure etched in the first step. The fourth contact hole 8 may be formed by removing the higher layers relative to the second n-type contact electrode layer 112 to expose a portion of the upper surface of the second n-type contact electrode layer 112.

Referring to FIG. 19, in the ninth step, in the vertically-stacked structure including the corner mesa contact structures, a fifth contact hole 12 is formed in the second direction, which, in the perspective view of the figure is transverse to the fourth contact hole 8, and in the first direction, which is vertical to the first corner mesa contact structure, to form a second contact structure on the surface of the vertically-stacked structure etched in the first step. The fifth contact hole 12 may be formed by removing the higher layers relative to the first n-type contact electrode layer 111 to expose a portion of the upper surface of the first n-type contact electrode layer 111.

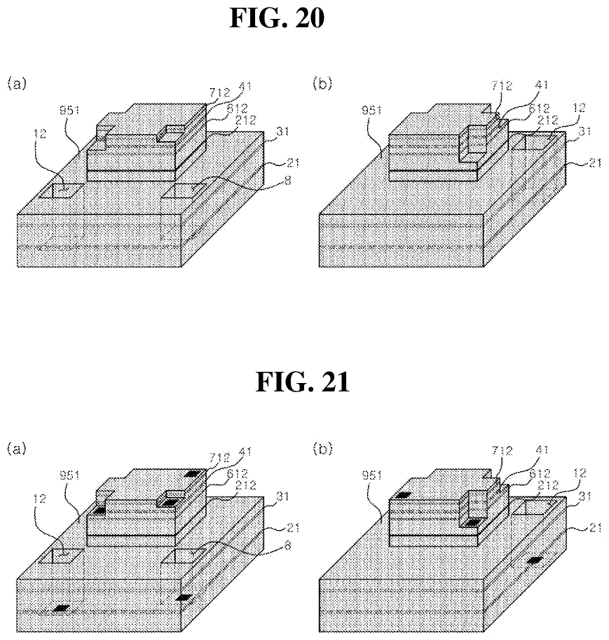

Referring to FIG. 20, in the tenth step, a passivation layer 951 is deposited on the vertically-stacked structure. The passivation layer 951 may be made of the same material used for depositing the passivation layer in the first embodiment but is not limited thereto. The passivation layer 951 may be an insulating layer 901.

Referring to FIG. 21, in the eleventh step, the passivation layer 951 is etched for electrical connection of the contact structures.

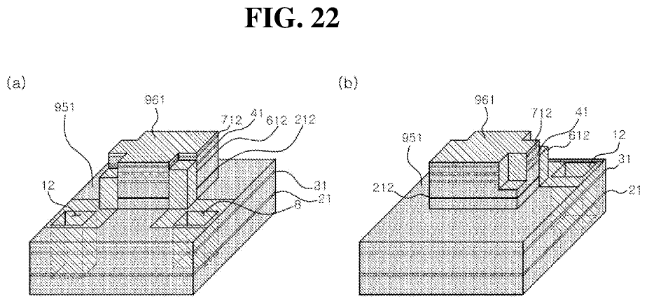

Referring to FIG. 22, in the twelfth step, a metal contact 961 is deposited on the etched vertically-stacked structure to manufacture an RGB micro-light-emitting diode that electrically connects the respective contact structures.

The metal contact 961 consists of a common contact electrode layer 801, a first wiring layer 811, and a second wiring layer 821. The first wiring layer 811 is formed on the exposed portions of the second n-type semiconductor layer 613 and the first n-type contact electrode layer 111, and the second wiring layer 821 is formed on the exposed portions of the third n-type semiconductor layer 711 and the second n-type contact electrode layer 112. The common contact electrode layer 801 is formed on the exposed portions of the common electrode layer 401 and the third p-type semiconductor layer 713 for electrically connecting each other.

According to the present inventive concept described above, the micro-light-emitting diode has a mesa structure formed at approximately right angles to the corners, thereby minimizing exposure of the active layer to the outside, thereby reducing the occurrence of surface recombination problems, which is a primary cause of leakage current. Because of this, the lifespan of the micro-light-emitting diode can be increased. Additionally, because the etching direction is perpendicular, manufacturing is easier.

Light-emitting structures that generate light with different wavelengths are vertically stacked on the substrate to reduce the unit area of the micro-light-emitting diode, and by means of current blocking layers, each of the light-emitting structures can be individually controlled.

### Brief Description of Reference Numerals

1, 2: first contact hole
3, 4: second contact hole
5, 6: third contact hole
7, 8: fourth contact hole
9, 12: fifth contact hole
10, 11: substrate
15: protective layer
20, 21: first current blocking layer
30, 31: second current blocking layer
40, 41: third current blocking layer
51, 52: first corner mesa contact structure
53, 54: second corner mesa contact structure
55, 56: third corner mesa contact structure
100, 110: n-type contact electrode layer
101, 111: first n-type contact electrode layer
102, 112: second n-type contact electrode layer
103, 113: third n-type contact electrode layer
200, 210: first light-emitting structure
201, 211: first n-type semiconductor layer
202, 212: first active layer p1 203, 213: first p-type semiconductor layer
300, 301: first tunnel junction layer
400, 401: common electrode layer
500, 501: second tunnel junction layer
600, 610: second light-emitting structure
601, 611: second p-type semiconductor layer
602, 612: second active layer
603, 613: second n-type semiconductor layer
700, 710: third light-emitting structure
701, 711: third n-type semiconductor layer
702, 712: third active layer
703, 713: third p-type semiconductor layer
800, 801: common contact electrode layer
810, 811: first wiring layer
820, 821: second wiring layer
900, 901: insulating layer
950, 951: passivation layer
960, 961: metal contact

While the inventive concept has been shown and described with reference to certain preferred embodiments thereof, it will be understood by those skilled in the art that various changes in form and details may be made therein without departing from the spirit and scope of the inventive concept as defined by the appended claims. Therefore, the scope of the inventive concept is defined not by the detailed description of the inventive concept but by the appended claims, and all differences within the scope will be construed as being included in the present inventive concept.

What is claimed is:

1. An RGB micro-light-emitting diode comprising:
a substrate;
a first n-type contact electrode layer formed on the substrate;
a second n-type contact electrode layer formed on the first n-type contact electrode layer;
a third n-type contact electrode layer formed on the second n-type contact electrode layer;
a first light-emitting structure formed on the third n-type contact electrode layer;
a first tunnel junction layer formed on the first light-emitting structure;
a common electrode layer formed on the first tunnel junction layer;
a second tunnel junction layer formed on the common electrode layer;
a second light-emitting structure formed on the second tunnel junction layer; and
a third light-emitting structure formed on the second light-emitting structure;
wherein the first light-emitting structure is connected to the third n-type contact electrode layer, the second light-emitting structure is connected to the first n-type contact electrode layer, and the third light-emitting structure is connected to the second n-type contact electrode layer, and
wherein the RGB micro-light-emitting diode comprises first to third corner mesa contact structures on the third n-type contact electrode layer.

2. The RGB micro-light-emitting diode of claim 1, further comprising:
a first current blocking layer formed between the first n-type contact electrode layer and the second n-type contact electrode layer;
a second current blocking layer formed between the second n-type contact electrode layer and the third n-type contact electrode layer; and
a third current blocking layer formed between the second light-emitting structure and the third light-emitting structure.

3. The RGB micro-light-emitting diode of claim 2, wherein the first to third current blocking layers consist of a p-type semiconductor or an insulating material, respectively.

4. The RGB micro-light-emitting diode of claim 1, further comprising:
a first tunnel junction layer formed between the first light-emitting structure and the common electrode layer; and
a second tunnel junction layer formed between the common electrode layer and the second light-emitting structure.

5. The RGB micro-light-emitting diode of claim 1, wherein the first tunnel junction layer and the second tunnel junction layer comprise n⁺⁺-GaN layers and p⁺⁺-GaN layers, respectively, which are sequentially stacked in a symmetrical structure with respect to the common electrode layer.

6. The RGB micro-light-emitting diode of claim 1, wherein the first light-emitting structure comprises a first n-type semiconductor layer, a first active layer, and a first p-type semiconductor layer, which are sequentially stacked,
wherein the second light-emitting structure comprises a second p-type semiconductor layer, a second active layer, and a second n-type semiconductor layer, which are sequentially stacked, and
wherein the third light-emitting structure comprises a third n-type semiconductor layer, a third active layer, a third p-type semiconductor layer.

7. The RGB micro-light-emitting diode of claim 6, comprising:
a first wiring layer electrically connecting the second n-type semiconductor layer and the first n-type contact electrode layer;
a second wiring layer electrically connecting the third n-type semiconductor layer and the second n-type contact electrode layer; and
a common contact electrode layer covering the exposed surface of the common electrode layer and the top of the third p-type semiconductor layer.

8. The RGB micro-light-emitting diode of claim 7, wherein the first wiring layer is formed on the exposed portions of the second n-type semiconductor layer and the first n-type contact electrode layer; and
wherein the second wiring layer is formed on the exposed portions of the third n-type semiconductor layer and the second n-type contact electrode layer.

9. The RGB micro-light-emitting diode of claim 1, wherein the first light-emitting structure generates light of a first wavelength, the second light-emitting structure generates light of a second wavelength that is longer than the first wavelength, and the third light-emitting structure generates light of a third wavelength that is longer than the second wavelength.

10. The RGB micro-light-emitting diode of claim 9, wherein the light of the first wavelength is blue (B), the light of the second wavelength is green (G), and the light of the third wavelength is red (R).

11. A method of manufacturing an RGB micro-light-emitting diode, comprising the steps of;
forming a first contact hole to form a first corner mesa contact structure on a vertically-stacked structure;
forming a second contact hole to form a second corner mesa contact structure in a first direction with respect to the first contact hole;
forming a third contact hole to form a third corner mesa contact structure in a second direction with respect to the second contact hole;
forming a fourth contact hole to form a first contact structure in a third direction with respect to the first contact hole;
forming a fifth contact hole to form a second contact structure in the first direction with respect to the first contact hole and in a direction which is diagonal with respect to the second contact hole;
forming a vertically-stacked structure including the corner mesa contact structures by etching the vertically-stacked structure, which includes the first contact hole at the first corner, the second contact hole at the second corner, the third contact hole at the third corner, and no contact hole at the fourth corner, into a rectangular shape to form a pixel mesa structure, down to the surface of the third n-type contact electrode layer;
depositing a passivation layer on the surface of the vertically-stacked structure including the corner mesa contact structures;
etching the passivation layer for electrode connection of the vertically-stacked structure; and
forming a metal contact to connect to the top of the vertically-stacked structure.

12. The method of manufacturing an RGB micro-light-emitting diode of claim 11 wherein the corner mesa contact structures comprise first to third corner mesa contact structures,
wherein the first corner mesa contact structure is formed by removing the higher layers relative to the common electrode layer to expose a portion of the upper surface of the common electrode layer,
wherein the second corner mesa contact structure is formed by removing the higher layers relative to the second n-type contact electrode layer to expose a portion of the second n-type contact electrode layer, and
wherein the third corner mesa contact structure is formed by removing the higher layers relative to the third n-type semiconductor layer to expose a portion of the upper surface of the third n-type semiconductor layer.

13. The method of manufacturing an RGB micro-light-emitting diode of claim 12, wherein the metal contact is used as a first wiring layer, a second wiring layer, and a common contact electrode layer,
wherein the first wiring layer electrically connects the second n-type contact electrode layer and the first n-type contact electrode layer,
wherein the second wiring layer electrically connects the third n-type contact electrode layer and the second n-type contact electrode layer, and
wherein the common contact electrode layer covers the exposed surface of the common electrode layer and the top of the third p-type semiconductor layer.

14. The method of manufacturing an RGB micro-light-emitting diode of claim 11 wherein the first contact hole is formed by removing the higher layers relative to the second n-type contact electrode layer to expose a portion of the upper surface of the second n-type contact electrode layer; and
wherein the second contact hole is formed by removing the higher layers relative to the first n-type contact electrode layer to expose a portion of the upper surface of the first n-type contact electrode layer.

15. A method of manufacturing an RGB micro-light-emitting diode, comprising the steps of;
forming a vertically-stacked structure including a pixel mesa structure by etching the vertically-stacked structure down to the top of a third n-type contact electrode layer;
depositing a protective layer including the pixel mesa structure on the third n-type semiconductor layer of the vertically-stacked structure including the pixel mesa structure;
removing a portion of the protective layer by performing chemical mechanical polishing (CMP) down to the top of a third p-type semiconductor layer to planarize the top of the protective layer and the pixel mesa structure;
forming a first contact hole to form a first corner mesa contact structure at a first corner of the pixel mesa structure;
forming a second contact hole to form a second corner mesa contact structure at a second corner of the pixel mesa structure in a first direction with respect to the first contact hole;
forming a third contact hole to form a third corner mesa contact structure at a third corner of the pixel mesa structure in a second direction with respect to the second contact hole;
forming a vertically-stacked structure including the first to third corner mesa contact structures by removing the remaining protective layer on the vertically-stacked structure;
forming a fourth contact hole to form a first contact structure in a third direction with respect to the first corner mesa contact structure on the third n-type semiconductor layer of the vertically-stacked structure;
forming a fifth contact hole to form a second contact structure spaced away from the fifth contact hole on the third n-type semiconductor layer of the vertically-stacked structure and in the same direction as the first corner mesa contact structure and the second corner mesa contact structure;
depositing a passivation layer on the surface of the vertically-stacked structure including the contact holes and the corner mesa contact structures;
etching the passivation layer for electrode connection of the vertically-stacked structure on which the passivation layer is deposited; and
forming a metal contact to connect to the top of the etched vertically-stacked structure.

16. The method of manufacturing an RGB micro-light-emitting diode of claim 15 wherein the corner mesa contact structures comprise first to third corner mesa contact structures,
wherein the first corner mesa contact structure is formed by removing the higher layers relative to the common electrode layer to expose a portion of the upper surface of the common electrode layer,
wherein the second corner mesa contact structure is formed by removing the higher layers relative to the second n-type contact electrode layer to expose a portion of the second n-type contact electrode layer, and
wherein the third corner mesa contact structure is formed by removing the higher layers relative to the third n-type semiconductor layer to expose a portion of the upper surface of the third n-type semiconductor layer.

17. The method of manufacturing an RGB micro-light-emitting diode of claim 16 wherein the metal contact is used as a first wiring layer, a second wiring layer, and a common contact electrode layer,
wherein the first wiring layer electrically connects the second n-type contact electrode layer and the first n-type contact electrode layer,
wherein the second wiring layer electrically connects the third n-type contact electrode layer and the second n-type contact electrode layer, and
wherein the common contact electrode layer covers the exposed surface of the common electrode layer and the top of the third p-type semiconductor layer.

18. The method of manufacturing an RGB micro-light-emitting diode of claim 15 wherein the first contact hole is formed by removing the higher layers relative to the second n-type contact electrode layer to expose a portion of the upper surface of the second n-type contact electrode layer; and
wherein the second contact hole is formed by removing the higher layers relative to the first n-type contact electrode layer to expose a portion of the upper surface of the first n-type contact electrode layer.
